(19) United States
(12) Patent Application Publication
(10) Pub. No.: US 2005/0200363 A1
(43) Pub. Date: Sep. 15, 2005

(54) Electrical inspection method and apparatus for printed wiring board for the electronic component mounting, and computer-readable recording medium

(75) Inventors: Hiroshi Hasegawa, Tokyo (JP); Yoshihiro Saeki, Tokyo (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD.

(21) Appl. No.: 11/078,842

(22) Filed: Mar. 11, 2005

(30) Foreign Application Priority Data
Mar. 12, 2004 (JP) 2004-71567

(51) Int. Cl. G01R 31/08

(52) U.S. Cl. 324/523

(57) ABSTRACT

An electrical inspection method and apparatus for film carrier tapes for the electronic component mounting, and a computer-readable recording medium for inspecting a wiring pattern without causing a defective appearance by discharge breakdown even when the wiring pattern has protrusions between wires. The inspection method comprises applying a first voltage V₁ between adjacent wires and measuring the current between the wires to detect the presence or absence of leakage current attributed to protrusions that extend from the respective wires and have an interval between the tips thereof within a predetermined range; and applying a second voltage V₂ between adjacent wires of the wiring pattern found to be free of leakage current and measuring the current between the wires to detect the presence or absence of leakage current attributed to protrusions that extend from the respective wires and have an interval between the tips thereof which is larger than the predetermined range. The protrusions having a specified small interval are detected before application of the second voltage V₂, so that a defective appearance can be prevented.

### FIELD OF THE INVENTION

The present invention relates to an electrical inspection method for performing electrical inspection of wiring patterns of a printed wiring board for insulation failure. The present invention is particularly suitable for the inspection of printed wiring boards for the electronic component mounting, including flexible printed wiring boards such as FPC and film carrier tapes (TAB (tape automated bonding) tapes, COF (chip on film) tapes, BGA (ball grid array) tapes, CSP (chip size package) tapes, ASIC (application specific integrated circuit) tapes, 2-metal (double-sided wiring) tapes and multilayer wiring tapes), and rigid printed wiring boards having glass epoxy substrates. Herein, the term “printed wiring boards for the electronic component mounting” refers to printed wiring boards on which electronic components have been mounted as well as pre-mounting printed wiring boards.

### BACKGROUND OF THE INVENTION

Flexible film carrier tapes (FPC and TAB tapes, for example) and rigid PWB (printed wiring boards) for the electronic component mounting are employed for incorporation of electronic components such as IC (integrated circuits) and LSI (large-scale integrations) into equipment that has a flat panel display, such as cellular phones, personal computers and TV sets, as well as printers.

The printed wiring boards for the electronic component mounting are quality inspected before and after the mounting of electronic components. Specifically, the wiring patterns are inspected for defects such as electrical disconnection, short-circuits, flaws, protrusions, defective plating, deformation of the tape and imperfect solder resist.

With the film carrier tapes for the electronic component mounting, for example TAB tapes, an electrical inspection apparatus as shown in FIG. 1 is used to inspect the wiring patterns for electrical disconnection and short-circuit (insulation failure). (See JP-A-H06-174774.) FIG. 2 illustrates an exemplary film carrier tape (TAB tape) to be inspected with the electrical inspection apparatus. The illustrated film carrier tape 11 includes wiring patterns 12, an insulating film 13, inner leads 14, outer leads 15, device holes 16, and sprocket holes 17 for transportation of the tape. The wiring patterns 12 are aligned on the insulating film, for example a polyimide film, along a longitudinal direction of the film carrier tape, forming pieces 11a, 11b, etc. The wiring patterns 12 are covered with solder resist layers 18 over area other than the inner leads 14 and the outer leads 15.

The electrical inspection apparatus of FIG. 1 is used as follows: A film carrier tape fed from a reel is set in the inspection apparatus. When an operator inputs an instruction to start measurement, the apparatus automatically carries out inspection with respect to each piece following the program. The piece to be inspected is placed on an inspection stage 1, and a conductive rubber plate 3 attached to the end of a head 2 movable in X, Y and Z directions, is brought into contact with the input and output inner leads 14.

On the other hand, probe pins 5 supported by probe cards 4 are moved to make contact with the input and output outer leads 15. When there are test pads at ends of the outer leads 15, the probe pins 5 are contacted with the pads.

Conductance is checked in this state to inspect all the wires for disconnection at once. Subsequently, a short-circuit inspection is performed. In the short-circuit (insulation failure) inspection, the head 2 is moved to separate the conductive rubber plate 3 away from the inner leads 14, whilst the contacts between the probe pins 5 and the outer leads 15 are maintained. In this state, a voltage is applied between adjacent wires and the current is measured. For example, the applied voltage is 20 V and the current is measured with use of an ammeter having a lower detection limit of 1 μA.

The insulation failure in wiring patterns occurs most frequently due to insufficient etching for the conductive metal (for example copper) which leads to protrusions extending from the adjacent wires in the width direction, and also due to the presence of minute foreign substances between the adjacent wires. FIGS. 3 and 4 are a top view and a sectional view respectively showing protrusions extending from the wires. As illustrated, protrusions 21 extend from the adjacent wires 12a and face away from each other with an interval or width W between the tips thereof. Because the wire pitches in recent years are reduced to 30 μm (15 μm spacing), the insulation failure ascribed to the protrusions or foreign substances is more likely to occur. In the following description, the term “protrusions” will refer to the wire protrusions indicated by the numeral 21 in FIGS. 3 and 4, and foreign substances present between the wires that lower the insulation resistance (or cause insulation failure). The foreign substances are for example metal powder from transportation reels, foreign objects from human body, and solder resist pieces.

The above-described electrical inspection apparatus detects insulation failure arising from the protrusions 21 when a leakage current over 1 μA is measured under application of 20 V between wires. Thus, the presence or absence of insulation failure attributed to the protrusions 21 with an interval W of 0.2 to 0.3 μm can be determined.

However, it is impossible to detect the current between the protrusions 21 with an interval W of above 0.5 μm, due to the reason given below: The interval W in the range of 0.2 to 0.3 μm corresponds to a resistance of several tens of MΩ, so that the leakage current attributed to the protrusions 21 can be measured by applying a voltage of about 20 V, with use of an ammeter having a lower detection limit of 1 μA. On the other hand, the interval W of 0.5 m corresponds to a resistance of nearly 1 GΩ and therefore the leakage current caused by the protrusions 21 is undetectable. Without detection of the leakage current, the wiring pattern that has protrusions with an interval of over 0.5 μm is determined to be non-defective in the short-circuit (insulation failure) inspection.

When a film carrier is used for mounting a driver IC of liquid crystal display, it is often necessary that the flexible film carrier based on a polyimide film or the like be folded for installation. When the film carrier has a wiring pattern containing protrusions with an interval W of about 0.5 μm, the folding can result in short-circuit attributed to the protrusions.

Therefore, it is required that the short-circuit (insulation failure) inspection detect leakage current attributed to the protrusions with a relatively large interval W between the tips thereof. One way of achieving this is to apply a higher voltage. The applied voltage of about 200 V in combination with use of an ammeter having a lower detection limit of 0.1 μA permits detection of leakage current caused by the protrusions with an interval W of about 0.5 μm.

However, when a voltage of 200 V is applied between the wires, the protrusions with an interval W of less than 0.5 μm, for example 0.2 to 0.3 μm, are discharged and burnt off. As a result, pseudo insulation is produced between the protrusions and the short-circuit (insulation failure) inspection results in positive. However, the discharge burns off part of the solder resist layer 18, with formation of pinholes. Since the discharge occurs momentarily, the electrical inspection apparatus cannot detect the protrusions. The pieces in which pinholes are formed in the solder resist layer by the discharge breakdown must be sorted out by visual inspection, which is very difficult because of minuteness of the pinholes.

The present invention has been made to solve the aforesaid problems of the prior art. It is therefore an object of the invention to provide an electrical inspection method and apparatus for film carrier tapes for the electronic component mounting, and also a computer-readable recording medium whereby a wiring pattern can be inspected speedily without suffering defective appearance by discharge breakdown even when the wiring pattern has protrusions between wires with a relatively large interval such that short-circuit is likely to result when the film carrier is folded.

### DISCLOSURE OF THE INVENTION

An electrical inspection method for printed wiring boards for the electronic component mounting according to the present invention, which method determines the presence or absence of insulation failure in a wiring pattern by measuring leakage current between adjacent wires under application of a voltage between the adjacent wires comprises:
applying a first voltage V₁ between adjacent wires and measuring the current between the wires to detect the presence or absence of leakage current; and
applying a second voltage V₂ that is larger than the first voltage V₁ between adjacent wires of the wiring pattern found to be free of leakage current, and measuring the current between the wires to detect the presence or absence of leakage current.

An electrical inspection method for printed wiring boards for the electronic component mounting according to the present invention comprises:
applying a first voltage V₁ between adjacent wires and measuring the current between the wires to detect the presence or absence of leakage current attributed to protrusions that extend from the respective wires and have an interval between the tips thereof within a predetermined range; and
applying a second voltage V₂ between adjacent wires of the wiring pattern found to be free of leakage current and measuring the current between the wires to detect the presence or absence of leakage current attributed to protrusions that extend from the respective wires and have an interval between the tips thereof which is larger than the predetermined range.

In the electrical inspection method, the second voltage V₂ has an electrical force that causes discharge breakdown between protrusions to produce pseudo insulation when the second voltage V₂ is applied between wires that have protrusions with an interval between the tips thereof within the predetermined range.

An electrical inspection method for printed wiring boards for the electronic component mounting according to the present invention, which method determines the presence or absence of insulation failure in a wiring pattern by measuring leakage current between adjacent wires under application of a voltage between the adjacent wires comprises:
applying a first voltage V₁ between adjacent wires and measuring the current between the wires using first current measuring means to detect the presence or absence of leakage current; and
applying a second voltage V₂ that is equal to or larger than the first voltage V₁ between adjacent wires of the wiring pattern found to be free of leakage current, and measuring the current between the wires using second current measuring means to detect the presence or absence of leakage current, the second current measuring means being capable of measuring a lower current than the first current measuring means.

An electrical inspection method for printed wiring boards for the electronic component mounting according to the invention comprises:
applying a first voltage V₁ between adjacent wires and measuring the current between the wires using first current measuring means to detect the presence or absence of leakage current attributed to protrusions that extend from the respective wires and have an interval between the tips thereof within a predetermined range; and
applying a second voltage V₂ between adjacent wires of the wiring pattern found to be free of leakage current and measuring the current between the wires using second current measuring means to detect the presence or absence of leakage current attributed to protrusions that extend from the respective wires and have an interval between the tips thereof which is larger than the predetermined range.

The above electrical inspection methods further comprises:
contacting a conductive elastic member with input and output inner leads, contacting probe pins with input and output outer leads, applying a voltage through the probe pins, and measuring the current between wires to determine the presence or absence of disconnection in a wiring pattern; and
separating the conductive elastic member away from the inner leads, applying a voltage through the probe pins, and measuring the current between wires to determine the presence or absence of insulation failure in the wiring pattern.

An electrical inspection apparatus for printed wiring boards for the electronic component mounting according to the present invention comprises:
a stage on which a piece to be electrically inspected is placed;
probe pins that are brought into contact with outer leads of the piece placed on the stage;
voltage application means for applying a voltage between adjacent wires of the piece through the probe pins;
current measuring means for measuring the current between the adjacent wires of the piece through the probe pins; and
control means that controls the voltage application means to apply a first voltage V₁ between adjacent wires, the current measuring means to measure the current between the wires, the voltage application means to apply a second voltage V₂ that is larger than the first voltage V₁ between adjacent wires of the wiring pattern found to be free of leakage current, and the current measuring means to measure the current between the wires.

In the electrical inspection apparatus:
the voltage application means applies a first voltage V₁ between adjacent wires;
the current measuring means measures the current between the wires to detect the presence or absence of leakage current attributed to protrusions that extend from the respective wires and have an interval between the tips thereof within a predetermined range;
the voltage application means applies a second voltage V₂ between adjacent wires of the wiring pattern found to be free of leakage current; and
the current measuring means measures the current between the wires to detect the presence or absence of leakage current attributed to protrusions that extend from the respective wires and have an interval between the tips thereof which is larger than the predetermined range.

In the electrical inspection apparatus, the voltage application means applies a second voltage V₂ having an electrical force that causes discharge breakdown between protrusions to produce pseudo insulation when the second voltage V₂ is applied between wires that have protrusions with an interval between the tips thereof within the predetermined range.

An electrical inspection apparatus for printed wiring boards for the electronic component mounting according to the present invention comprises:
a stage on which a piece to be electrically inspected is placed;
probe pins that are brought into contact with outer leads of the piece placed on the stage;
voltage application means for applying a voltage between adjacent wires of the piece through the probe pins;
first current measuring means for measuring the current between the adjacent wires of the piece through the probe pins;
second current measuring means for measuring the current between the adjacent wires of the piece through the probe pins, the second current measuring means being capable of measuring a lower current than the first current measuring means; and
control means that controls the voltage application means to apply a first voltage V₁ between adjacent wires, the first current measuring means to measure the current between the wires, the voltage application means to apply a second voltage V₂ that is equal to or larger than the first voltage V₁ between adjacent wires of the wiring pattern found to be free of leakage current, and the second current measuring means to measure the current between the wires.

In the electrical inspection apparatus:
the voltage application means applies a first voltage V₁ between adjacent wires;
the first current measuring means measures the current between the wires to detect the presence or absence of leakage current attributed to protrusions that extend from the respective wires and have an interval between the tips thereof within a predetermined range;
the voltage application means applies a second voltage V₂ between adjacent wires of the wiring pattern found to be free of leakage current; and
the second current measuring means measures the current between the wires to detect the presence or absence of leakage current attributed to protrusions that extend from the respective wires and have an interval between the tips thereof which is larger than the predetermined range.

A computer-readable recording medium according to the present invention comprises a program recorded therein that is executed by a computer to carry out processing, the processing comprising:
a step in which voltage application means applies a first voltage V₁ between adjacent wires of a wiring pattern of a printed wiring board for the electronic component mounting;
a step in which current measuring means measures the current between the adjacent wires;
a step in which the voltage application means applies a second voltage V₂ that is larger than the first voltage V₁ between adjacent wires of the wiring pattern found to be free of leakage current in the measurement by the current measuring means; and
a step in which the current measuring means measures the current between the adjacent wires.

A computer-readable recording medium according to the present invention comprises a program recorded therein that is executed by a computer to carry out processing, the processing comprising:
a step in which voltage application means applies a first voltage V₁ between adjacent wires of a wiring pattern of a printed wiring board for the electronic component mounting;
a step in which first current measuring means measures the current between the adjacent wires;
a step in which the voltage application means applies a second voltage V₂ that is equal to or larger than the first voltage V₁ between adjacent wires of the wiring pattern found to be free of leakage current in the measurement by the first current measuring means; and
a step in which second current measuring means measures the current between the adjacent wires, the second current measuring means being capable of measuring a lower current than the first current measuring means.

According to the electrical inspection method and apparatus, and the program recorded on the computer-readable recording medium of the invention, inspection can be performed without causing defective appearance due to discharge breakdown even when a wiring pattern has protrusions between wires with a relatively large interval such that insulation failure is likely to result when the film carrier is folded. This effect is achieved by carrying out the inspection in a manner such that a first voltage V₁ is applied between adjacent wires to detect the presence or absence of leakage current, and subsequently a second voltage V₂ that is larger than the first voltage V₁ is applied to detect the presence or absence of leakage current.

In another embodiment of the invention, the current between the wires is measured with the first current measuring means to detect the presence or absence of leakage current, and the current between the wires is subsequently measured with the second current measuring means capable of measuring a lower current than the first current measuring means, thereby detecting the presence or absence of leakage current. Accordingly, the electrical inspection for insulation failure by high insulation resistance measurement under a service voltage of a printed wiring board can be performed speedily in substantially the same time as the conventional one-stage measurement, so as to detect protrusions that have a relatively large interval to the extent that insulation failure is caused afterward.

### BRIEF DESCRIPTION OF THE DRAWINGS

FIG. 1 is a view illustrating a configuration of an electrical inspection apparatus for inspecting a film carrier tape for disconnection and short-circuit;

FIG. 2 is a top view of an exemplary film carrier tape (TAB tape);

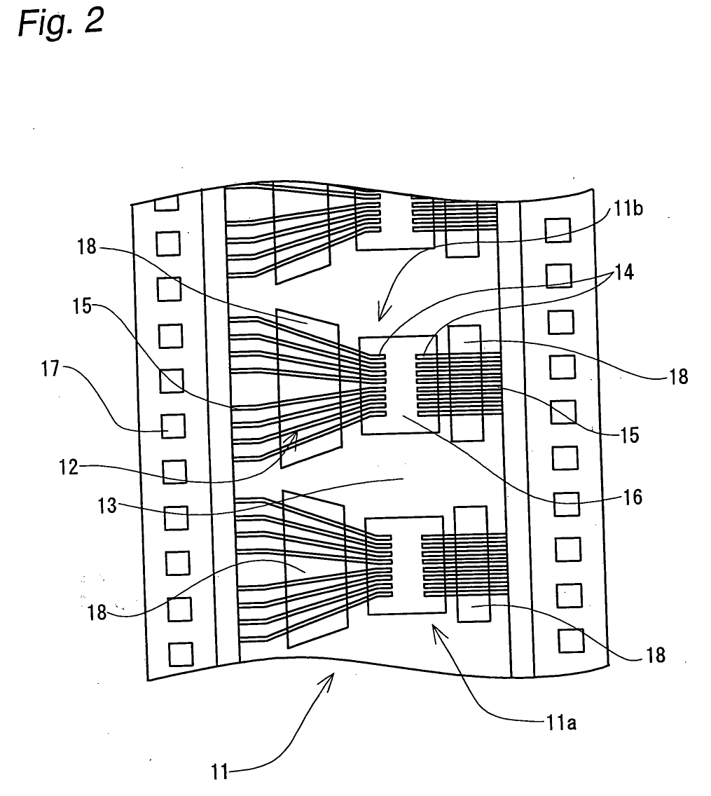

FIG. 3 is a top view of protrusions that extend from wires;

FIG. 4 is a cross-sectional view of the protrusions extending from the wires;

FIG. 5 is a view explaining a constitution of a computer that controls operations of an electrical inspection apparatus according to an embodiment of the present invention;

FIG. 6 is a flow chart showing a control routine executed by the computer shown in FIG. 5;

FIG. 7 is a view explaining a constitution of a computer that controls operations of an electrical inspection apparatus according to another embodiment of the present invention; and

FIG. 8 is a flow chart showing a control routine executed by the computer shown in FIG. 7; wherein:

1. Inspection stage
2. Head
3. Conductive rubber plate
4. Probe card
5. Probe pin
8. Ammeter
8a. First ammeter
8b. Second ammeter
9. Voltage application part
11. Film carrier tape
11a. Piece
11b. Piece
12. Wiring pattern
12a. Wire
13. Insulating film
14. Inner lead
15. Outer lead
16. Device hole
17. Sprocket hole
18. Solder resist layer
21. Protrusion
30. Computer
31. CPU
32. RAM
33. I/O
34. Bus
35. Hard disk
36. CD-ROM driver
37. Keyboard
38. Mouse
39. Display

### BEST MODE FOR CARRYING OUT THE INVENTION

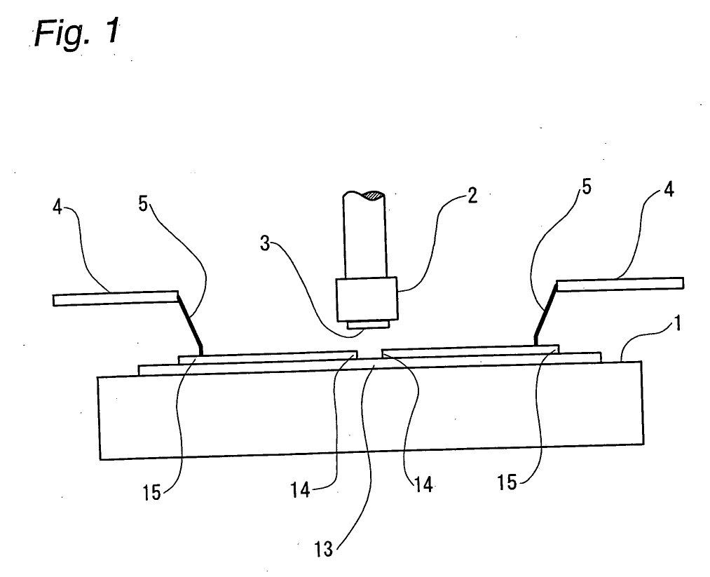

Hereinbelow, embodiments of the present invention will be described with reference to the drawings. The embodiments employ an apparatus having the same configuration as illustrated in FIG. 1, with alteration of software. As described above, a film carrier tape fed from a reel is set in the inspection apparatus, and automatic operation is initiated with an instruction input by an operator. A piece to be inspected is placed on an inspection stage 1, and a conductive rubber plate 3 is brought into contact with input and output inner leads 14. Meanwhile, probe pins 5 are contacted with input and output outer leads 15, and disconnection is checked in this state. After the disconnection inspection, a short-circuit (insulation failure) inspection is carried out.

In the short-circuit (insulation failure) inspection, a head 2 is moved to separate the conductive rubber plate 3 away from the inner leads 14, whilst the contacts between the probe pins 5 and the outer leads 15 are maintained. Subsequently, a voltage is applied between predetermined adjacent wires 12a, and the current is measured. For example, this measurement is performed with use of an ammeter having a lower detection limit in the range of 0.00001 to 1 μA, preferably 0.0001 to 0.5 μA, and more preferably 0.001 to 0.1 μA. In the present embodiment, a detection range-selectable ammeter is used with the lower detection limit set at 0.1 μA.

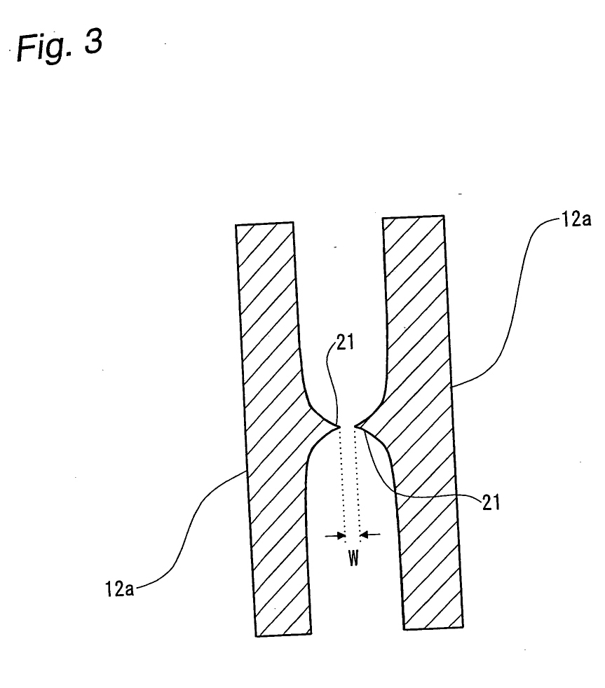

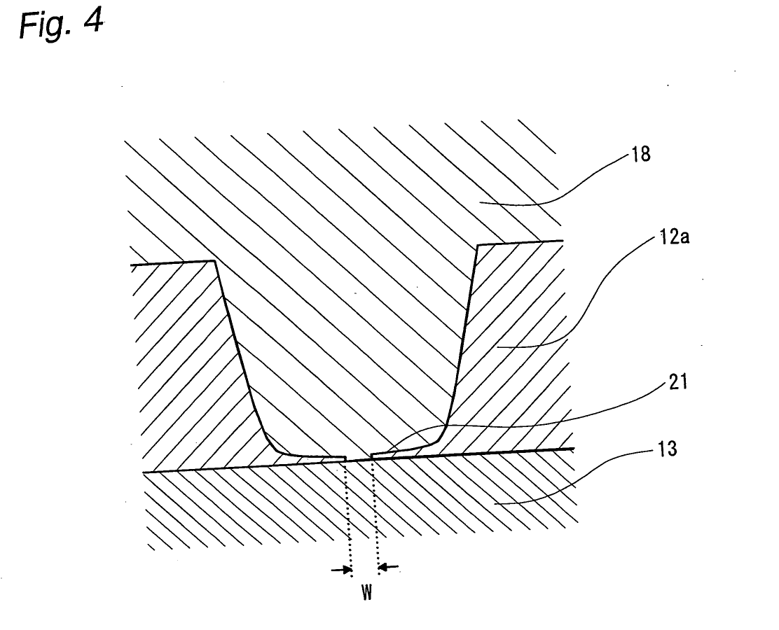

First, the current is measured under application of a voltage of, for example, 20 V. In this measurement, the piece is determined to be defective when a current exceeding 1 μA is detected. The short-circuit detected herein is attributed to protrusions 21 with an interval W of about 0.2 to 0.3 μm or below, as illustrated in FIGS. 3 and 4.

The piece that has passed the above inspection is subjected to application of 200 V and the current is measured. In this measurement, the piece is determined to be defective when a current exceeding 0.2 μA is detected. The short-circuit detected herein is attributed to protrusions 21 with an interval W of approximately above 0.5 μm, as illustrated in FIGS. 3 and 4.

After the short-circuit (insulation failure) inspection, the probe pins 5 are separated from the outer leads 15. The film carrier tape is then transported by one pitch and the next piece is placed on the inspection stage, followed by the above procedures.

In the present embodiment as described above, the first inspection is performed at 20 V to detect the presence or absence of insulation failure attributed to wire protrusions with an interval W of about 0.2 to 0.3 μm or less; thereafter the second inspection is carried out at 200 V to detect the presence or absence of insulation failure attributed to wire protrusions with an interval W of above 0.5 μm. When a voltage of 200 V is applied to the wiring pattern that has protrusions with an interval W of about 0.2 to 0.3 μm, discharge breakdown (discharge phenomenon) occurs with the results of pseudo insulation between the wires and formation of pinholes to cause defective appearance. However, in the present embodiment, such protrusions are inspected in advance under application of a lower voltage. That is, the protrusions, if any, in the piece subjected to a higher voltage have an interval of above 0.5 μm. Accordingly, the film carrier tape can be inspected for protrusions with an interval of up to about 0.5 μm without causing defective appearance. The relationship among the applied voltage, interval W, short-circuit inspectability and occurrence of defective appearance are summarized in Table 1.

TABLE 1

| Applied | | |
|---|---|---|
| voltage | Interval W (0.2-0.3 μm) | Interval W (0.5 μm) |
| 20 V | AA | CC₁ |
| 200 V | CC₂ | AA |

AA: Insulation failure inspectable
CC₁: Insulation failure uninspectable
CC₂: defective appearance by discharge breakdown

As described above, the electrical inspection method of the present embodiment makes it possible to inspect a wiring pattern for defects without causing defective appearance by discharge breakdown even when the wiring pattern has protrusions between wires with an interval that is relatively large but not enough to allow easy visual inspection with eyes and that is relatively large such that short-circuit is likely to occur when the film carrier is folded. The inspection method does not require a drastically increased inspection time as compared to the conventional methods.

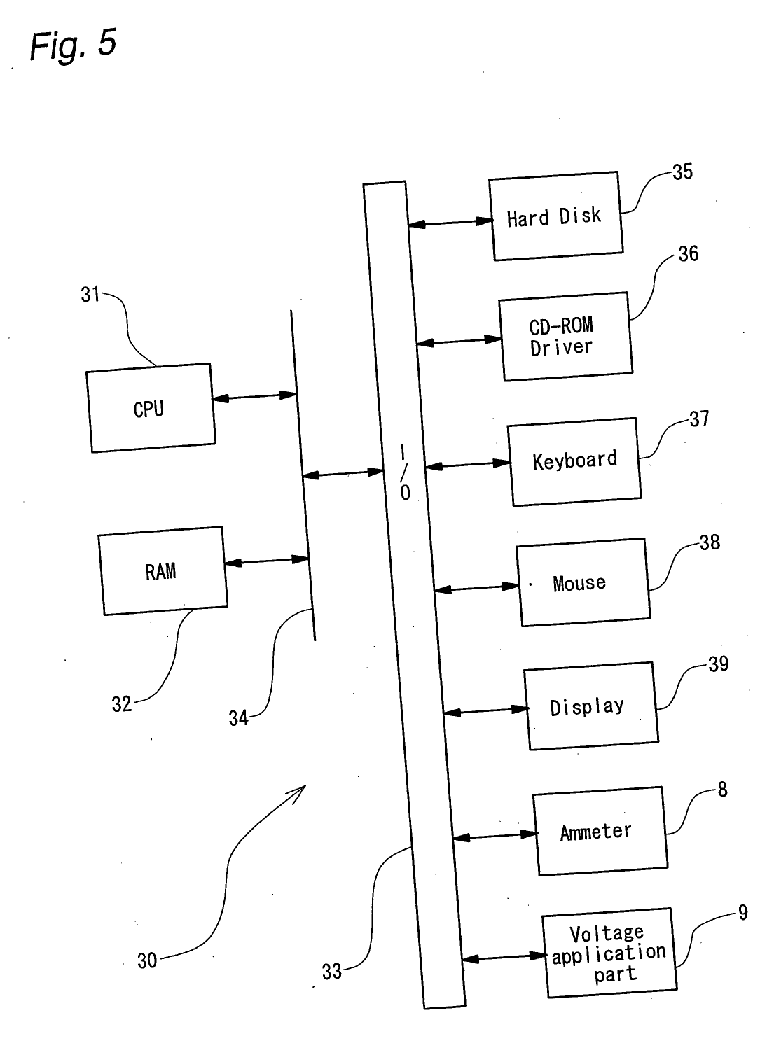

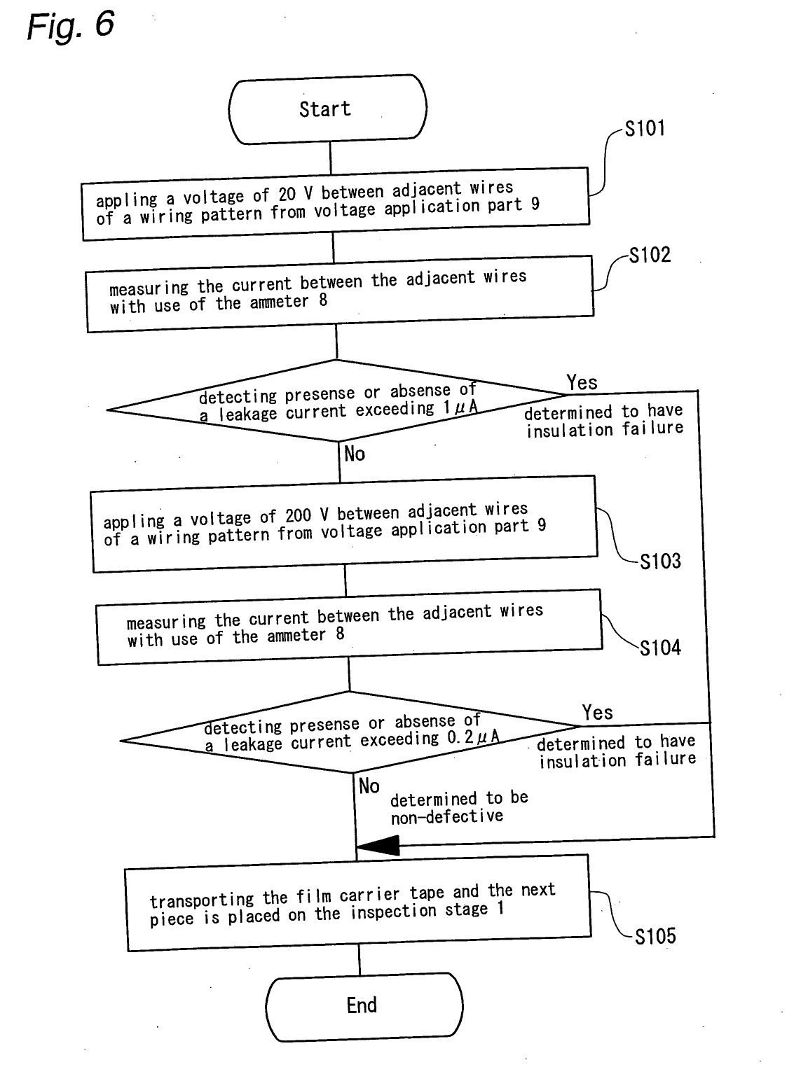

A control routine carried out in the present embodiment will be described with reference to FIGS. 5 and 6. FIG. 5 shows a constitution of control means (computer) that controls operations of the electrical inspection apparatus used in the present embodiment. The computer 30 includes CPU 31, RAM 32 and I/O (input/output device) 33 that are connected via buses 34. The I/O 33 is connected with an ammeter 8, a voltage application part 9, a hard disk 35, a CD-ROM driver 36, a keyboard 37, a mouse 38 and a display 39.

In the present embodiment, the computer 30 controls the electrical inspection following a control program. To execute the control, the computer 30 reads the control program stored in a CD-ROM, into the RAM 32. Alternatively, the computer may read the program previously installed on the hard disk 35. FIG. 6 is a flow chart of a control routine in which the computer 30 executes the following steps:

First, the voltage application part 9 applies a voltage of 20 V between adjacent wires of a wiring pattern of a piece to be inspected that is placed on the inspection stage 1 illustrated in FIG. 1. (Step 101)

Subsequently, the ammeter 8 measures the current between the adjacent wires. (Step 102)

When the ammeter 8 detects a leakage current that exceeds a predetermined threshold (1 μA), the piece is determined to have insulation failure. The film carrier tape is then transported and the next piece is placed on the inspection stage 1, followed by the above procedures. (Step 105)

When no leakage current is detected, the voltage application part 9 applies a voltage of 200 V between adjacent wires of the wiring pattern. (Step 103)

Subsequently, the ammeter 8 measures the current between the adjacent wires. (Step 104)

When the ammeter 8 detects a leakage current that exceeds a predetermined threshold (0.2 μA), the wiring pattern is determined to have insulation failure. When the detected current is 0.2 μA or below, the piece is determined to be non-defective. The film carrier tape is then transported and the next piece is placed on the inspection stage 1, followed by the above procedures. (Step 105)

Next, another embodiment of the present invention will be presented. Unlike the above-described embodiment which uses an ammeter having a lower detection limit of 0.1 μA, the present embodiment employs an apparatus provided with a first ammeter and a second ammeter having a lower detection limit of 1 μA and 0.01 μA respectively. After the disconnection inspection has been performed in a manner described above, the head 2 shown in FIG. 1 is moved to separate the conductive rubber plate 3 away from the inner leads 14, whilst the contacts between the probe pins 5 and the outer leads 15 are maintained. In this state, a short-circuit (insulation failure) inspection is performed, as described below.

First, a voltage of 20 V is applied between predetermined adjacent wires 12a, and the current is measured using the first ammeter having a lower detection limit of 1 μA. In this measurement, the piece is determined to be defective when a current exceeding 1 μA is detected. The short-circuit detected herein is attributed to protrusions 21 with an interval W of about 0.2 to 0.3 μm or below, as illustrated in FIGS. 3 and 4.

The piece that has passed the above inspection is subjected to application of 20 V, and the current between wires is measured with the second ammeter having a lower detection limit of 0.01 μA. In this measurement, the piece is determined to be defective when a current exceeding 0.02 pA is detected. The short-circuit detected herein is attributed to protrusions 21 with an interval W of approximately above 0.5 μm, as illustrated in FIGS. 3 and 4.

After the short-circuit (insulation failure) inspection, the probe pins 5 are separated from the outer leads 15. The film carrier tape is then transported by one pitch and the next piece is placed on the inspection stage, followed by the above procedures.

The ammeters having a lower detection limit of 0.01 μA, such as the second ammeter are capable of measuring a minute amount of electric current as compared to those ammeters conventionally used in traditional inspection apparatuses that have relatively high detection limits, for example 1 μA. Since such low current needs to be measured stably distinguished from noise, the measurement takes a long time when a high-resistance object is present, as in between wires of a printed wiring board for the electronic component mounting that is composed of an insulator and conductive metal wirings. The present embodiment solves this problem by measuring the electric current with the first ammeter having a lower detection limit of 1 μA, and subsequently measuring the current with the second ammeter having a lower detection limit of 0.01 μA. That is, the first ammeter speedily detects the presence or absence of insulation failure attributed to the wire protrusions with an interval W of about 0.2 to 0.3 μm or below, and the second ammeter detects the presence or absence of insulation failure attributed to the wire protrusions with an interval W of above 0.5 μm. Accordingly, the inspection of a film carrier tape having protrusions with an interval of up to about 0.5 μm can be expedited to a level comparable with the conventional inspection methods.

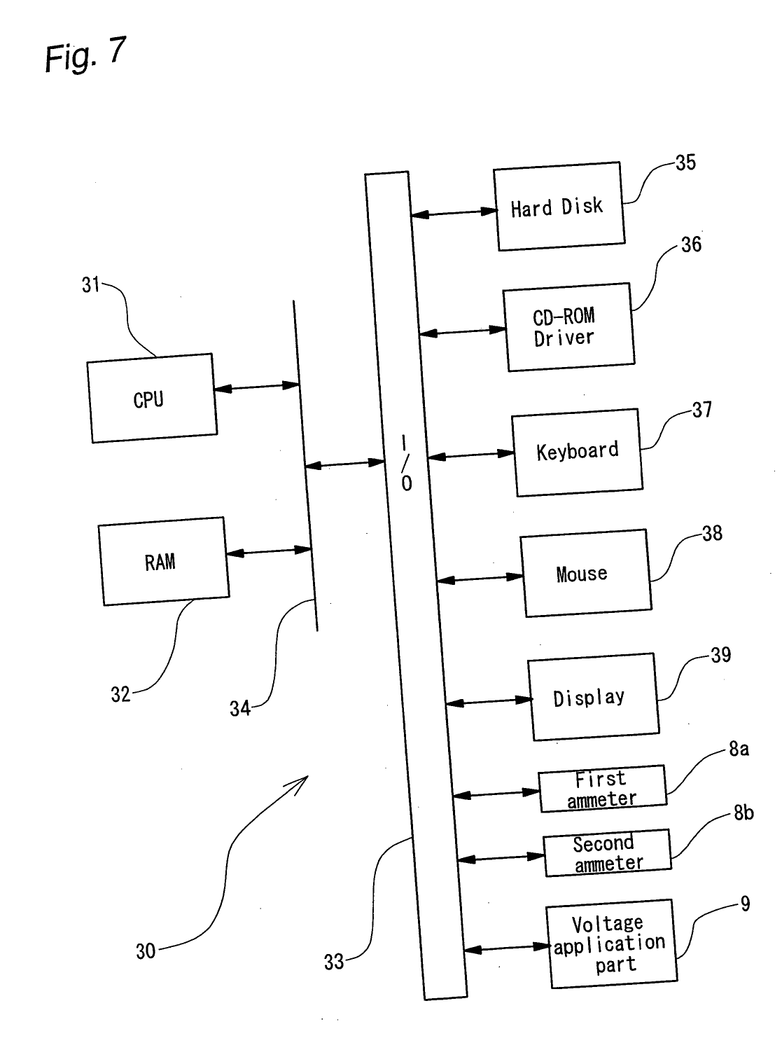

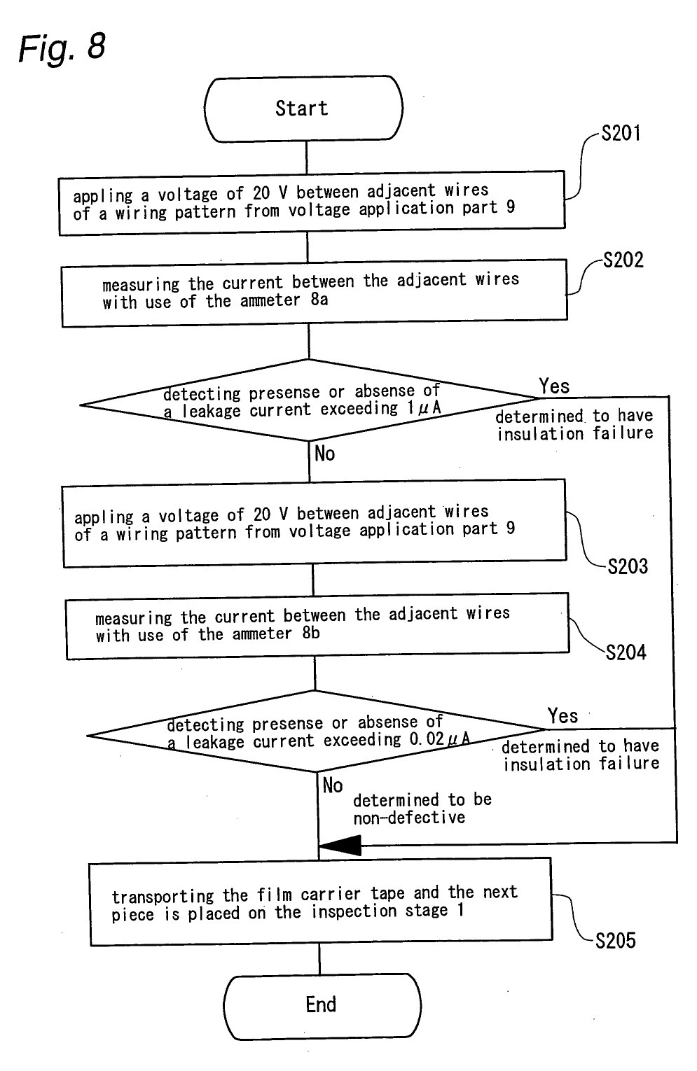

A control routine carried out in this embodiment will be described with reference to FIGS. 7 and 8. FIG. 7 shows a constitution of control means (computer) that controls operations of the electrical inspection apparatus used in the present embodiment. The computer 30 includes CPU 31, RAM 32 and I/O (input/output device) 33 that are connected via buses 34. The I/O 33 is connected with a first ammeter 8a having a lower detection limit of 1 μA, a second ammeter 8b having a lower detection limit of 0.01 μA, a voltage application part 9, a hard disk 35, a CD-ROM driver 36, a keyboard 37, a mouse 38 and a display 39. For example, in the present embodiment, the computer 30 executes control of the electrical inspection following a control program that is read into the RAM 32 from the hard disk 35.

FIG. 8 is a flow chart of a control routine in which the computer 30 executes the following steps:

First, the voltage application part 9 applies a voltage of 20 V between adjacent wires of a wiring pattern of a piece to be inspected that is placed on the inspection stage 1 illustrated in FIG. 1. (Step 201) Subsequently, the first ammeter 8a measures the current between the adjacent wires. (Step 202)

When the first ammeter 8a detects a leakage current that exceeds a predetermined threshold (1 μA), the piece is determined to have insulation failure. The film carrier tape is then transported and the next piece is placed on the inspection stage 1, followed by the above procedures. (Step 205)

When no leakage current is detected, the voltage application part 9 applies a voltage of 20 V between adjacent wires of the wiring pattern. (Step 203)

Subsequently, the second ammeter 8b measures the current between the adjacent wires. (Step 204)

When the second ammeter 8b detects a leakage current that exceeds a predetermined threshold (0.02 μA), the wiring pattern is determined to have insulation failure. When the detected current is 0.02 μA or below, the piece is determined to be non-defective. The film carrier tape is then transported and the next piece is placed on the inspection stage 1, followed by the above procedures. (Step 205)

Although the present invention has been explained by the above embodiments of inspection of the film carrier tape, it will be appreciated that the present invention is not limited to the embodiments and various modifications, adjustments and alterations are possible within the scope of the present invention. For example, the measurement conditions such as voltage may be adjusted appropriately depending on the type of the insulating resin of the printed wiring board for the electronic component mounting, the material, shape and method for formation of the wiring patterns, and the wire interval.

In the present invention, a first voltage V₁ is applied between adjacent wires and the current between the wires is measured to detect the presence or absence of leakage current attributed to protrusions that extend from the respective wires and have an interval between the tips thereof within a predetermined range; thereafter adjacent wires of the wiring pattern found free of leakage current are subjected to application of a second voltage V₂ that is larger than the first voltage V₁ and has an electric force that causes discharge breakdown to produce pseudo insulation when applied between wires that have protrusions with an interval between the tips thereof within the predetermined range, and the current between the wires is measured to determine the presence or absence of leakage current attributed to protrusions that have an interval between the tips thereof which is larger than the predetermined range. Thus, the invention permits inspection of a wiring pattern that has protrusions between wires with a relatively large interval, for insulation failure without causing defective appearance due to discharge breakdown.

Alternatively, the electrical inspection according to the present invention may be carried out as follows: A first voltage V₁ is applied between adjacent wires and the current between the wires is measured using first current measuring means to detect the presence or absence of leakage current attributed to protrusions that extend from the respective wires and have an interval between the tips thereof within a predetermined range. Subsequently, adjacent wires of the wiring pattern found free of leakage current are subjected to application of a second voltage V₂ that is equal to or larger than the first voltage V₁, and the current between the wires is measured using second current measuring means capable of measuring a lower current than the first current measuring means, thereby to detect the presence or absence of leakage current attributed to protrusions that have an interval between the tips thereof which is larger than the predetermined range. Thus, the inspection for insulation failure can be performed speedily without causing defective appearance due to discharge breakdown even when the wiring pattern has protrusions with a relatively large interval.

The present invention will be further illustrated below with reference to the following Examples, which however in no way limit the scope of the invention.

### EXAMPLE 1

With use of the electrical inspection apparatus described in the above embodiment, electrical inspection for wire disconnection and short-circuit was performed with respect to a film carrier tape for liquid crystal panel that had wiring patterns in which the wire pitch was 30 μm (line 15 μm, space 15 μm). The inspection was conducted for 10,000 pieces. The first and second ammeters had a lower detection limit of 1 μA and 0.1 μA respectively.

The inspection of short-circuit was designed to reject pieces in which the wire protrusions had an interval of about 0.5 μm or less. Accordingly, the pass/fail criteria was 1 μA or above in the first measurement under 20 V, and 0.2 μA or above in the second measurement under 200 V. Thereafter, the pieces that had passed the above electrical inspection were visually inspected over a period of twice the usual time. The visual inspection confirmed no defective appearance that seemed to be attributed to discharge phenomenon at the wire protrusions under application of 200 V.

These pieces, with the test pads inclusive, were punched out from the film carrier tape using a die. Each film carrier piece was folded along a slit and was tested using an electrical inspection apparatus designed specifically for short-circuit (insulation failure) inspection. The inspection confirmed no defective that seemed to be ascribed to the excessively close wire protrusions.

### COMPARATIVE EXAMPLE 1

With use of an electrical inspection apparatus including an insulation failure detection program in which the lower detection limit was 1 μA and the insulation failure detection voltage was 20 V, electrical inspection for wire disconnection and short-circuit (insulation failure) was performed with respect to a film carrier tape for liquid crystal panel that had wiring patterns in which the wire pitch was 30 μm. The inspection was conducted for 10,000 pieces.

The inspection was designed to reject pieces in which the wire protrusions had an interval of about 0.2 to 0.3 μm or less. Accordingly, the pass/fail criteria was 1 μA or above in the measurement under 20 V. Thereafter, the pieces that had passed the above electrical inspection were visually inspected over a period of twice the usual time. The inspection confirmed no defective appearance that seemed to be attributed to discharge phenomenon at the wire protrusions.

These pieces, with the test pads inclusive, were punched out from the film carrier tape using a die. Each film carrier piece was folded along a slit and was tested using an electrical inspection apparatus designed specifically for short-circuit (insulation failure) inspection. The inspection confirmed short circuit in three pieces.

### COMPARATIVE EXAMPLE 2

With use of an electrical inspection apparatus including an insulation failure detection program in which the lower detection limit was 0.1 μA and the insulation failure detection voltage was 200 V, electrical inspection for wire disconnection and short-circuit (insulation failure) was performed with respect to a film carrier tape for liquid crystal panel that had wiring patterns in which the wire pitch was 30 μm. The inspection was conducted for 10,000 pieces.

The inspection was designed to reject pieces in which the wire protrusions had an interval of about 0.5 μm or less. Accordingly, the pass/fail criteria was 0.2 μA or above in the measurement under 200 V. Thereafter, the pieces that had passed the above electrical inspection were visually inspected over a period of twice the usual time. The inspection confirmed pinholes in two pieces. This result indicates that these pieces had contained wire protrusions with an interval in the range of 0.2 to 0.3 μm, and discharge breakdown was caused between the protrusions by high voltage application to burn off part of the solder resist layer, with formation of pinholes.

1. An electrical inspection method for printed wiring boards for the electronic component mounting, which method determines the presence or absence of insulation failure in a wiring pattern by measuring leakage current between adjacent wires under application of a voltage between the adjacent wires, the method comprising:
applying a first voltage V₁ between adjacent wires and measuring the current between the wires to detect the presence or absence of leakage current; and
applying a second voltage V₂ that is larger than the first voltage V₁ between adjacent wires of the wiring pattern found to be free of leakage current, and measuring the current between the wires to detect the presence or absence of leakage current.

2. The electrical inspection method for printed wiring boards for the electronic component mounting according to claim 1, the method comprising:
applying a first voltage V₁ between adjacent wires and measuring the current between the wires to detect the presence or absence of leakage current attributed to protrusions that extend from the respective wires and have an interval between the tips thereof within a predetermined range; and
applying a second voltage V₂ between adjacent wires of the wiring pattern found to be free of leakage current and measuring the current between the wires to detect the presence or absence of leakage current attributed to protrusions that extend from the respective wires and have an interval between the tips thereof which is larger than the predetermined range.

3. The electrical inspection method for printed wiring boards for the electronic component mounting according to claim 2, wherein the second voltage V₂ has an electrical force that causes discharge breakdown between protrusions to produce pseudo insulation when the second voltage V₂ is applied between wires that have protrusions with an interval between the tips thereof within the predetermined range.

4. An electrical inspection method for printed wiring boards for the electronic component mounting, which method determines the presence or absence of insulation failure in a wiring pattern by measuring leakage current between adjacent wires under application of a voltage between the adjacent wires, the method comprising:
applying a first voltage V₁ between adjacent wires and measuring the current between the wires using first current measuring means to detect the presence or absence of leakage current; and
applying a second voltage V₂ that is equal to or larger than the first voltage V₁ between adjacent wires of the wiring pattern found to be free of leakage current, and measuring the current between the wires using second current measuring means to detect the presence or absence of leakage current, the second current measuring means being capable of measuring a lower current than the first current measuring means.

5. The electrical inspection method for printed wiring boards for the electronic component mounting according to claim 4, the method comprising:
applying a first voltage V₁ between adjacent wires and measuring the current between the wires using first current measuring means to detect the presence or absence of leakage current attributed to protrusions that extend from the respective wires and have an interval between the tips thereof within a predetermined range; and
applying a second voltage V₂ between adjacent wires of the wiring pattern found to be free of leakage current and measuring the current between the wires using second current measuring means to detect the presence or absence of leakage current attributed to protrusions that extend from the respective wires and have an interval between the tips thereof which is larger than the predetermined range.

6. The electrical inspection method for printed wiring boards for the electronic component mounting according to claim 1, the method further comprising:
contacting a conductive elastic member with input and output inner leads, contacting probe pins with input and output outer leads, applying a voltage through the probe pins, and measuring the current between wires to determine the presence or absence of disconnection in a wiring pattern; and
separating the conductive elastic member away from the inner leads, applying a voltage through the probe pins, and measuring the current between wires to determine the presence or absence of insulation failure in the wiring pattern.

7. An electrical inspection apparatus for printed wiring boards for the electronic component mounting, the apparatus comprising:
a stage on which a piece to be electrically inspected is placed;
probe pins that are brought into contact with outer leads of the piece placed on the stage;
voltage application means for applying a voltage between adjacent wires of the piece through the probe pins;
current measuring means for measuring the current between the adjacent wires of the piece through the probe pins; and
control means that controls the voltage application means to apply a first voltage V₁ between adjacent wires, the current measuring means to measure the current between the wires, the voltage application means to apply a second voltage V₂ that is larger than the first voltage V₁ between adjacent wires of the wiring pattern found to be free of leakage current, and the current measuring means to measure the current between the wires.

8. The electrical inspection apparatus for printed wiring boards for the electronic component mounting according to claim 7, wherein:
the voltage application means applies a first voltage V₁ between adjacent wires;
the current measuring means measures the current between the wires to detect the presence or absence of leakage current attributed to protrusions that extend from the respective wires and have an interval between the tips thereof within a predetermined range;
the voltage application means applies a second voltage V₂ between adjacent wires of the wiring pattern found to be free of leakage current; and
the current measuring means measures the current between the wires to detect the presence or absence of leakage current attributed to protrusions that extend from the respective wires and have an internal between the tips thereof which is larger than the predetermined range.

9. The electrical inspection apparatus for printed wiring boards for the electronic component mounting according to claim 8, wherein the voltage application means applies a second voltage V₂ having an electrical force that causes discharge breakdown between protrusions to produce pseudo insulation when the second voltage V₂ is applied between wires that have protrusions with an interval between the tips thereof within the predetermined range.

10. An electrical inspection apparatus for printed wiring boards for the electronic component mounting, the apparatus comprising:
a stage on which a piece to be electrically inspected is placed;
probe pins that are brought into contact with outer leads of the piece placed on the stage;
voltage application means for applying a voltage between adjacent wires of the piece through the probe pins;
first current measuring means for measuring the current between the adjacent wires of the piece through the probe pins, second current measuring means for measuring the current between the adjacent wires of the piece through the probe pins, the second current measuring means being capable of measuring a lower current than the first current measuring means; and
control means that controls the voltage application means to apply a first voltage V₁ between adjacent wires, the first current measuring means to measure the current between the wires, the voltage application means to apply a second voltage V₂ that is equal to or larger than the first voltage V₁ between adjacent wires of the wiring pattern found to be free of leakage current, and the second current measuring means to measure the current between the wires.

11. The electrical inspection apparatus for printed wiring boards for the electronic component mounting according to claim 10, wherein:
the voltage application means applies a first voltage V₁ between adjacent wires;
the first current measuring means measures the current between the wires to detect the presence or absence of leakage current attributed to protrusions that extend from the respective wires and have an interval between the tips thereof within a predetermined range;
the voltage application means applies a second voltage V₂ between adjacent wires of the wiring pattern found to be free of leakage current; and
the second current measuring means measures the current between the wires to detect the presence or absence of leakage current attributed to protrusions that extend from the respective wires and have an interval between the tips thereof which is larger than the predetermined range.

12. A computer-readable recording medium comprising a program recorded therein that is executed by a computer to carry out processing, the processing comprising:
a step in which voltage application means applies a first voltage V₁ between adjacent wires of a wiring pattern of a printed wiring board for the electronic component mounting;
a step in which current measuring means measures the current between the adjacent wires;
a step in which the voltage application means applies a second voltage V₂ that is larger than the first voltage V₁ between adjacent wires of the wiring pattern found to be free of leakage current in the measurement by the current measuring means; and
a step in which the current measuring means measures the current between the adjacent wires.

13. A computer-readable recording medium comprising a program recorded therein that is executed by a computer to carry out processing, the processing comprising:
a step in which voltage application means applies a first voltage V₁ between adjacent wires of a wiring pattern of a printed wiring board for the electronic component mounting;
a step in which first current measuring means measures the current between the adjacent wires;
a step in which the voltage application means applies a second voltage V₂ that is equal to or larger than the first voltage V₁ between adjacent wires of the wiring pattern found to be free of leakage current in the measurement by the first current measuring means; and
a step in which second current measuring means measures the current between the adjacent wires, the second current measuring means being capable of measuring a lower current than the first current measuring means.
